(19) United States
(12) Patent Application Publication
(10) Pub. No.: US 2017/0011887 A1
(43) Pub. Date: Jan. 12, 2017

(54) UV-ASSISTED REACTIVE ION ETCH FOR COPPER

(71) Applicant: Applied Materials, Inc., Santa Clara, CA (US)

(72) Inventors: Subhash Deshmukh, Livermore, CA (US); Jingjing Liu, Milpitas, CA (US); He Ren, San Jose, CA (US)

(21) Appl. No.: 15/273,645

(22) Filed: Sep. 22, 2016

Related U.S. Application Data
(62) Division of application No. 14/201,892, filed on Mar. 9, 2014.
(60) Provisional application No. 61/779,296, filed on Mar. 13, 2013.
(60) Provisional application No. 61/787,243, filed on Mar. 15, 2013.

(51) Int. Cl. H01J 37/32; C23F 4/00

(52) U.S. Cl. CPC H01J 37/32155; H01J 37/32128; C23F 4/00; H01J 2237/334

(57) ABSTRACT

The invention includes generating a plasma from a process gas for etching copper on a substrate; providing DC bias pulses to the substrate; exposing at least one of the plasma and the substrate to UV light while the DC bias pulses are provided to the substrate. Numerous other aspects are provided.

### RELATED APPLICATIONS

This application is a divisional of and claims priority to U.S. patent application Ser. No. 14/201,892 filed Mar. 9, 2014, and titled “UV-ASSISTED REACTIVE ION ETCH FOR COPPER” (Attorney Docket No. 17818/USA), which claims priority to U.S. Provisional Application No. 61/779,296 filed Mar. 13, 2013, and entitled “PULSED DC PLASMA ETCHING PROCESS AND APPARATUS” (Attorney Docket No. 17758/L) and U.S. Provisional Application No. 61/787,243 filed Mar. 15, 2013, and entitled “UV-ASSISTED REACTIVE ION ETCH FOR COPPER” (Attorney Docket No. 17818/L), each of which is hereby incorporated by reference herein for all purposes.

### FIELD

The present invention relates generally to semiconductor device manufacturing, and more particularly to plasma processes and apparatus.

### BACKGROUND

Within semiconductor substrate manufacturing, a plasma etching process may be used to remove one or material layers or films, or form patterns or the like in a substrate (e.g., form a patterned silicon wafer). As critical dimensions keep shrinking, it becomes desirable to more tightly control the etching process in order to achieve good trench profile, within wafer uniformity, and more precise critical dimension (CD) control.

One prior etching process uses a pulsing of a plasma radio-frequency (RF) source. RF source control may lead to relatively separate control of ion (reactive etchant) density and energy distribution, so as to widen the process window. The pulsing may be synchronized to provide improved process control in RF positive/negative cycles. However, RF pulsing techniques may have drawbacks in terms of complicated implementation and difficulty in reaching precise control.

In other implementations, a DC bias may be applied to a pedestal to control etchant energy. However, such DC biased processes suffer from the disadvantage of a narrow process window.

Accordingly, improved etching methods and apparatus are desired for improved CD control.

### SUMMARY

In some embodiments, a plasma etching apparatus is provided for etching copper that includes (1) a chamber body having a process chamber adapted to receive a substrate; (2) an RF source coupled to an RF electrode; (3) a pedestal located in the processing chamber and adapted to support a substrate; and (4) a UV source configured to delivery UV light to the processing chamber during at least a portion of an etch process performed within the plasma etching apparatus.

In some embodiments, a copper plasma etching method is provided that includes (1) providing a substrate within a process chamber; (2) providing a process gas to the process chamber; (3) exposing the process gas in the process chamber to RF pulses; (4) plasma etching the substrate within the process chamber; and (5) exposing at least one of the process gas and substrate to UV light during at least a portion of the plasma etching.

In some embodiments, a copper plasma etching method is provided that includes (1) providing a substrate within a process chamber; (2) providing a process gas to the process chamber; (3) exposing the process gas in the process chamber to RF energy to generate a plasma within the process chamber; (4) plasma etching the substrate within the process chamber; and (5) exposing at least one of the process gas and substrate to UV light during at least a portion of the plasma etching. Numerous other aspects are provided.

Other features and aspects of the present invention will become more fully apparent from the following detailed description of example embodiments, the appended claims, and the accompanying drawings.

### BRIEF DESCRIPTION OF THE DRAWINGS

FIG. 1 illustrates a partial side plan view of a substrate etching apparatus according to embodiments provided herein.

FIG. 2A illustrates a partial top view of a DC bias conductor pin assembly illustrating possible positions of the DC bias conductor pins according to embodiments provided herein.

FIG. 2B illustrates a side view of a DC bias conductor pin assembly according to embodiments provided herein.

FIG. 3 illustrates a graphical plot of RF Pulse and DC bias pulse relative to a master clock pulse according to embodiments provided herein.

FIG. 4 illustrates a flowchart of a plasma etching method according to embodiments provided herein.

FIG. 5 illustrates a partial side plan view of a substrate etching apparatus according to embodiments provided herein.

FIG. 6 is a schematic illustration of anisotropic and isotropic components of a Cu etch process according to embodiments provided herein.

FIG. 7A illustrates a schematic cross-sectional view of an interconnect formed by a Dual Damascene process.

FIG. 7B illustrates a schematic cross-sectional view of an interconnect formed by dry etching in which blanket copper layers are etched to form the interconnect according to embodiments provided herein.

FIGS. 8A and 8B are cross sectional views of example torroidal plasma chambers according to some embodiments provided herein.

### DETAILED DESCRIPTION

The use of copper in place of aluminum as the interconnect material for semiconductor devices has grown in popularity due to copper's lower resistivity and higher electromigration resistance. Unlike aluminum, however, the etching of copper is challenging due to non-volatile etch byproducts generated during copper etching, and the lack of effective post-etch cleaning techniques.

To avoid the above-mentioned drawbacks, damascene processes have been employed in which lines, trenches and vias are formed in dielectric layers, and these features are lined with one or more barrier layers prior to copper fill. The barrier layers act as diffusion barriers to copper and prevent copper penetration into the dielectric layers and underlying silicon substrate. No bulk copper etch is employed.

As device dimensions shrink, particularly below about 20 nanometers, the use of barrier layers becomes difficult as the barrier layer thickness may consume most of the feature to be filled with copper. Additionally, at a node size of 20 nanometers or less, and particularly at a node size of about 10 nanometers or less, sidewall/grain boundary scattering and electromigration affect RC delay and degrade device performance.

Embodiments described herein relate to apparatus and methods for dry etching copper. The ability to dry etch copper allows direct patterning of copper lines and interconnects (e.g., eliminating the need for damascene processes). As dry etched copper features are formed from blanket copper layers, such etched copper features have larger grain sizes and much lower resistivity. The copper features may be isolated using a low k dielectric fill. Use of a dielectric fill of low k material decreases damage to the low k material (when compared to performing a copper fill with a damascene process), resulting in reduced resistance and RC properties.

In some embodiments, a copper dry etching process is provided that employs ultra-violet (UV) irradiation to enhance the copper dry etch process. The UV irradiation provides a supplemental energy source for driving the etch process and facilitating etch residue removal at lower process temperatures. The use of a lower etch temperature allows for more control during etch by balancing etch rate with uniformity and profile considerations, while UV assisted residue removal allows for greater control over isotropic reactions and a larger process window.

In some embodiments, UV light having a wavelength of about 150-400 nanometers, or about 3 eV-8 eV of energy, and/or a flux rate of about 1×10¹⁵-1×10¹⁸ photons/(cm²-min) may be employed. Other wavelengths, energies and/or flux rates may be employed.

One suitable gas for dry etching of copper is H₂. In a hydrogen plasma, atomic hydrogen and hydrogen ions may be formed from a molecular hydrogen source and etch a copper surface through the formation of copper hydride (CuH) and copper dihydride (CuH₂):

2Cu+H₂→2CuH (1)

Cu+H₂→CuH₂ (2)

For reactions (1) and (2) to occur, atomic hydrogen may be supplied from a hydrogen plasma. DC bias provides directional, high energy hydrogen ions to enable a more anisotropic etch. However, sufficient surface energy must be provided to break Cu—Cu bonds to allow copper-hydrogen bonding with the copper being etched. This energy may be provided thermally, for example. In some embodiments, UV light (represented as “hν” below) may be employed to provide the energy to drive formation of volatile 2CuH and CuH₂:

Cu(s)+hν→Cu⁺+e (3)

Use of UV light to break Cu—Cu surface bonds may allow reduced substrate temperatures to be employed during etching, providing greater etch control through reduced etch rate. In some embodiments, a substrate etch temperature of less than about 200° C. may be employed, and in some embodiments, a substrate etch temperature of about 100° C. or less may be employed. Reduced substrate etch temperatures also prevent thermal damage to delicate surface structures such as narrow trenches and vias. Other substrate etch temperatures may be used.

In other embodiments, Cl₂ may be employed for dry etching copper. In a chlorine plasma, atomic chlorine and chlorine ions may be formed from molecular chlorine and etch a copper surface through the formation of copper chloride (CuCl or CuCl₂) and various other copper-chlorine species as shown below:

xCl(g)+e→xCl⁻(g) (4)

Cu(s)+Cl⁻(g)→CuCl(s) (5)

3CuCl(s)+hν→Cu₃Cl₃(g) (6)

CuCl(s)+hν→CuCl(g) (7)

CuCl₂(g)+e→CuCl₂⁻ (8)

CuCl(g)+Cl(g)→CuCl₂(g) (9)

CuCl⁻(g)+Cl(g)→CuCl₂(g)+e (10)

CuCl₂⁻(g)+Cu(g)+Cl(g)→Cu₂Cl₃(g)+3 (11)

Cu₂Cl₂⁻(g)+Cl(g)→Cu₂Cl₃(g) (12)

3CuCl₂(s)+3H(g)→Cu₃Cl₃(g)+3HCl(g) (13)

To reduce formation buildup of solid copper-chlorine byproducts, it is desirable to form gaseous byproducts that can be pumped from an etch chamber. In some embodiments, UV light is employed to convert solid copper-chlorine byproducts such as CuCl into gaseous byproducts such as Cu₂Cl₃(g) and CuCl(g) as indicated by equations (6) and (7) above.

As described above, UV light also may be used to break Cu—Cu surface bonds, which may allow reduced substrate temperatures to be employed during etching, providing greater etch control through reduced etch rate. In some embodiments, a substrate etch temperature of less than about 200° C. may be employed, and in some embodiments, a substrate etch temperature of about 100° C. or less may be employed. Other substrate etch temperatures may be used.

Other etch species may benefit from UV irradiation. For example, in some embodiments, a UV light assisted oxygen etch may be employed for dry copper etching. UV light may lower the oxidation temperature at the copper surface, allowing reduced substrate heating during the etch. Other example etch species that may benefit from UV irradiation include, for example, CF₄, C₂F₄, C₄F₈, C₄F₈, etc. Other etch species may be used.

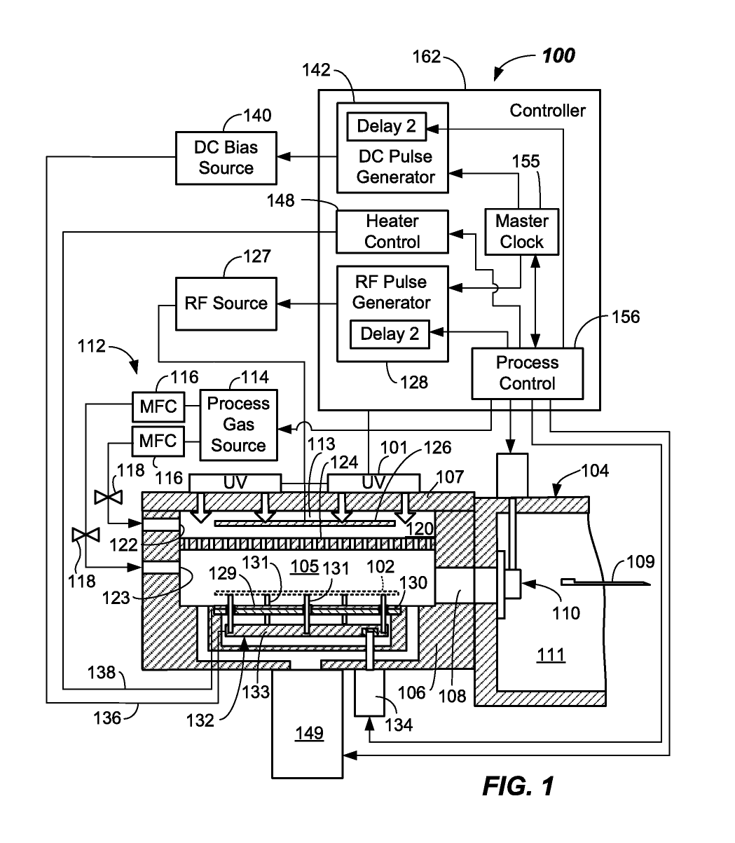

Any suitable etch chamber may be modified to include UV irradiation in accordance with the present invention. Example etch chambers include inductively-coupled plasma (ICP) chambers, capacitively-coupled plasma (CCP) chambers or the like. One example ICP chamber that may be modified to include UV irradiation is described in U.S. Pat. No. 6,453,842 titled “Externally Excited Torroidal Plasma Source Using A Gas Distribution Plate” which is hereby incorporated by reference herein in its entirety for all purposes. Example etch chambers and/or etch processes are described below with reference to FIGS. 1-8B.

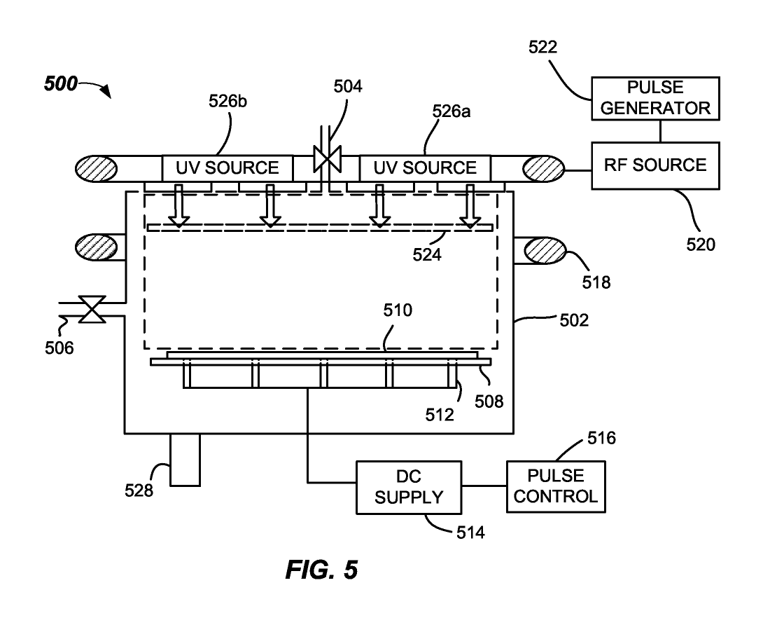

FIG. 5 illustrates a partial side plan of a substrate etching apparatus 500 according to embodiments provided herein. The etching apparatus includes a chamber 502 having top gas inlet 504 and side gas inlet 506 for supplying one or more process gases to the chamber 502. The chamber 502 includes a substrate support 508 for supporting a substrate 510 during etching. In some embodiments, a plurality of conducting pins 512 may contact and/or support the substrate 510 during etching. For example, the conducting pins 512 may provide a pulse DC bias to the substrate 510 to allow biasing of the substrate 510 during etching through use of DC supply 514 and pulse control 516.

The chamber 502 also includes an RF coil 518 for inductively supplying RF energy to the chamber 502 to generate a plasma. The RF energy may be supplied by an RF source 520, and may be pulsed in some embodiments (e.g., using pulse generator 522). A shower head 524 may help uniformly distribute gases supplied to the inlet 504.

In accordance with some embodiments, UV light may be provided to the chamber 502 from one or more UV sources 526a and/or 526b. In some embodiments, UV light having a wavelength of about 150-400 nanometers, or about 3 eV-8 eV of energy, and/or a flux rate of about 1×10¹⁵-1×10¹⁸ photons/(cm²-min) may be employed. Other wavelengths, energies and/or flux rates may be employed. UV light may be applied during any portion of the, or during the entire, etch process.

A pumping system 528 may be employed to evacuate the chamber to a desired pressure during etching, and/or to remove volatile etch species generated during etching.

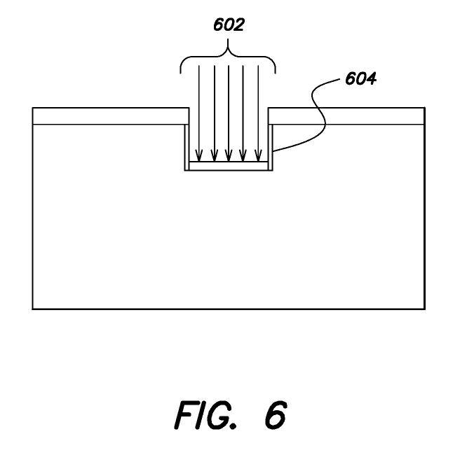

Use of pulsed DC bias of substrate 510 (e.g., using conductive pins 512, DC supply 514 and pulse control 516) and UV exposure may provide enhanced etch anisotropy and enhanced insitu byproduct desorption during Cu etching within the etching apparatus 500. For example, UV light source 526a and/or 526b provide a separate parameter for tuning isotropic etch reactions during Cu etching processes within the etching apparatus 500 by assisting in byproduct removal via reactions such as (1)-(13) described above and/or other UV assisted reactions. As stated, UV light may assist in breaking Cu-Cu surface bonds and may convert solid copper-chlorine byproducts into volatile gaseous byproducts that may be removed via pumping system 528. DC bias of the substrate can increase or otherwise tailor ion bombardment/directionality during plasma etching to individually control the anisotropic components of the etching process. Use of UV irradiation and DC bias control may allow formation of well-defined sidewall profiles as well as removal of etch byproducts at lower temperatures. See, for example, FIG. 6, which schematically illustrates control of the anisotropic and isotropic components of a Cu etch process by tuning with chemistry (e.g., with UV light) and plasma source (e.g., with DC bias). Example anisotropic interactions include ion assisted reactions, ion bombardment, etc., represented generally by arrows 602, with controls such as inductively coupled plasma (ICP), capacitively coupled plasma (CCP), DC bias, utility gas and/or the like. Example isotropic chemical reactions include radical reactions, molecule reactions, etc., such as at sidewalls 604, with controls such as reaction kinetics, temperature, UV light and/or the like.

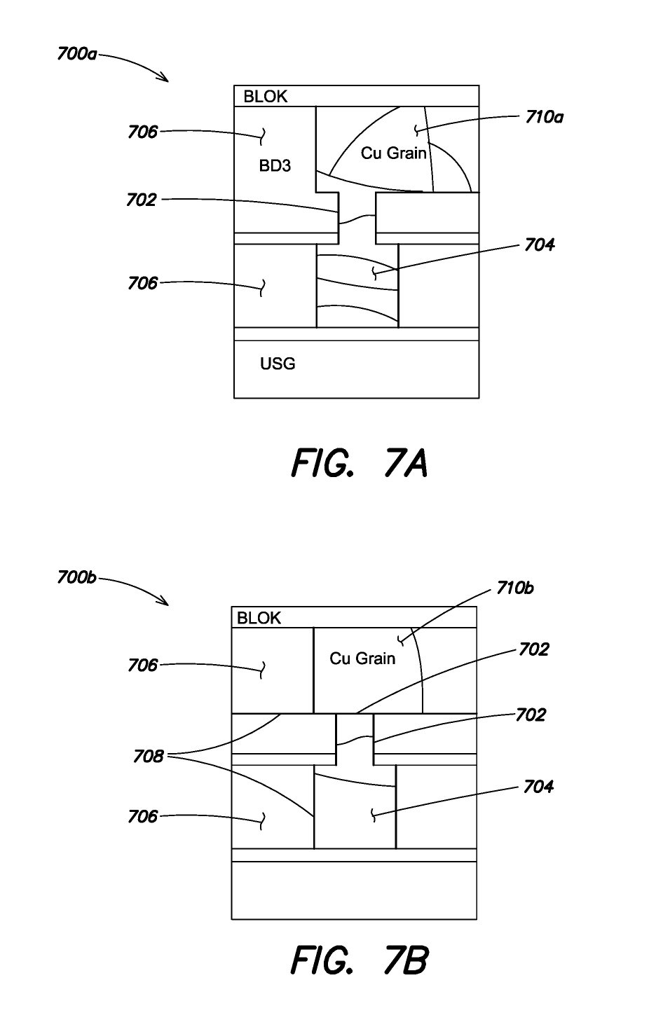

FIG. 7A illustrates a schematic cross-sectional view of an interconnect 700a formed by a Dual Damascene process. As stated, as feature size decreases, sidewall and grain boundary affects become significant. The interconnect 700a may use metal barrier layers 702 to separate metal layers or regions 704 (e.g., copper or another conductor) from dielectric layers or regions 706 (e.g., low-k or another dielectric material). FIG. 7B illustrates a schematic cross-sectional view of an interconnect 700b formed by dry etching in which blanket metal (e.g., copper) layers are etched to form the interconnect. The interconnect 700b may use dielectric barrier layers 708 to separate metal layers or regions 704 (e.g., copper or another conductor) from dielectric layers or regions 706 (e.g., low-k or another dielectric material) in some regions (e.g., line regions). Use of a dry etch process results in much less scattering from sidewall and grain boundaries (e.g., as blanket layers have a larger grain size than fill regions as shown by grain 710a of FIG. 7A versus grain 710b of FIG. 7B), and minimum dielectric damage.

In some embodiments, UV irradiation may be combined with use of an RF pulse source and a pulsed DC bias applied to the substrate. The pulsed DC bias may be provided through conductive DC bias pins that are provided in direct electrical contact with the substrate. The conductive DC bias pins may be part of a DC bias conductor assembly that lifts the substrate and also provides DC bias pulsing to the substrate to accomplish improved substrate etching. These and other aspects of embodiments of the invention are described below with reference to FIGS. 1-4 herein.

FIG. 1 illustrates a partially cross-sectioned side view of a substrate etching apparatus 100 and components thereof that may employ UV irradiation to improve copper etching. In some embodiments, UV light may be provided from a UV source 101 positioned on a lid 107 of the etching apparatus 100 as described further below.

The substrate etching apparatus 100 is adapted to couple to a mainframe section 104 and is configured and adapted to receive a substrate 102 within a process chamber 105 formed in a body 106 of the apparatus 100 and perform an etching process thereon. The substrate 102 may be any suitable substrate to be etched, such as a doped or un-doped silicon substrate, a III-V compound substrate, a silicon germanium (SiGe) substrate, an epi-substrate, a silicon-on insulator (SOI) substrate, a display substrate such as a liquid crystal display (LCD) substrate, a plasma display substrate, an electro luminescence (EL) lamp display substrate, a light emitting diode (LED) substrate, a solar cell array substrate, a solar panel substrate, or the like. Other substrates may be processed as well. In some embodiments, the substrate 102 may be a semiconductor wafer having a pattern or a mask formed thereon.

In some embodiments, the substrate 102 may have one or more layers disposed thereon. The one or more layers may be deposited in any suitable manner, such as by electroplating, chemical vapor deposition (CVD), physical vapor deposition (PVD), atomic layer deposition (ALD), or the like. The one or more layers may be any layers suitable for a particular device being fabricated.

For example, in some embodiments, the one or more layers may comprise one or more dielectric layers. In such embodiments, the one or more dielectric layers may comprise silicon oxide (SiO₂), silicon nitride (SiN), a low-k or high-k material, or the like. As used herein, low-k materials have a dielectric constant that is less than about that of silicon oxide (SiO₂). Accordingly, high-k materials have a dielectric constant greater than silicon oxide. In some embodiments, where the dielectric layer comprises a low-k material, the low-k material may be a carbon-doped dielectric material such as carbon-doped silicon oxide (SiOC), an organic polymer (such as polyimide, parylene, or the like), organic doped silicon glass (OSG), fluorine doped silicon glass (FSG), or the like. In embodiments where the dielectric layer is a high-k material, the high-k material may be hafnium oxide (HfO₂), zirconium oxide (ZrO₂), hafnium silicate (HfSiO), aluminum oxide (Al₂O₃), or the like. In some embodiments, the one or more layers may comprise one or more layers of a conductive material, for example such as a metal. In such embodiments, the metal may comprise copper (Cu), aluminum (Al), tungsten (N), titanium (Ti), cobalt (Co), alloys thereof, combinations thereof, or the like.

In some embodiments, the substrate 102 may include a patterned mask layer, which may define one or more features to be etched on the substrate 102. In some embodiments, the one or more features to be etched may be high aspect ratio features, wherein the one or more features have an aspect ratio of greater than about 10:1. The patterned, mask layer may be any suitable mask layer such as a hard mask, a photoresist layer, or combinations thereof. Any suitable mask layer composition may be used. The mask layer may have any suitable shape capable of providing an adequate template for defining the features to be etched into the one or more layers of the substrate 102. For example, in some embodiments, the patterned mask layer may be formed via an etching process. In some embodiments, the patterned mask layer may be utilized to define advanced or very small node devices (e.g., about 20 nm or smaller nodes). The patterned mask layer may be formed via any suitable technique, such as a spacer mask patterning technique.

The substrate etching apparatus 100 further includes a lid 107 comprising a portion of the body 106 that may be removable to service the process chamber 105. UV light source 101 may provide UV irradiation of the substrate 102 and/or the bulk plasma region of the process chamber 105. For example, one or more ports or windows may be formed in the lid 107 to allow UV light to be transmitted into the process chamber 105. UV light may be supplied at other locations, such as through a sidewall of the process chamber 105.

The body 106 includes a slit opening 108 that allows substrates 102 to be inserted into the process chamber 105 from a transfer chamber 111 by an end effector 109 of a robot (not shown) in order to undergo an etching process. The end effector 109 may remove the substrate 102 from the process chamber 105 following completion of the etching process thereat. The slit opening 108 may be sealed by a slit valve apparatus 110 during the process. Slit valve apparatus 110 may have a slit valve door covering the opening 108. Slit valve 110 may include any suitable slit valve construction, such as taught in U.S. Pat. Nos. 6,173,938; 6,347,918; and 7,007,919. In some embodiments, the slit valve 110 may be an L-motion slit valve, for example.

The substrate etching apparatus 100 also includes a gas supply assembly 112 configured and adapted to provide a process gas 113 into the process chamber 105. Gas supply assembly 112 may include a process gas source 114, one or more flow control devices, such as one or more mass flow controllers 116 and/or one or more flow control valves 118. The process gas source 114 may comprise one or more pressurized vessels containing one or more process gases.

In the depicted embodiment, a first process gas 113 may be provided into a pre-chamber 120 through first inlet 122 formed in a side wall of the body 106. A showerhead 124 having a plurality of passages formed therein separates the pre-chamber 120 from the process chamber 105 and functions to evenly distribute the first process gas 113 as the first process gas 113 flows into the process chamber 105. A second gas may be introduced directly into the process chamber 105 at a second inlet 123 at times. The second process gas may function to assist or enhance the process by synergistically reacting with the first gas 113, and to help clean the process chamber 105.

The first process gas 113 may comprise any gas or gases suitable to form plasma in order to etch the one or more layers and/or the substrate 102, For example, in some embodiments the first process gas or gases may comprise at least one of a hydrofluorocarbon (CxHyFz), a halogen containing gas such as chlorine (Cl₂) or bromine (Br₂), oxygen (O₂), nitrogen trifluoride (NF₃), sulfur hexafluoride (SF₆) , hydrogen gas (H₂), or the like. The first process gas may be provided at any suitable flow rate, for example, such as about 10 sccm to about 1,000 sccm.

Optionally, a carrier gas may be provided with or act as the first process gas 113. The carrier gas may be any one or more inert gases, such as nitrogen (N₂), helium (He), argon (Ar), xenon (Xe), or the like. In some embodiments, the carrier gas may be provided at a flow rate of about 10 sccm to about 1000 sccm.

In the depicted embodiment, an RF electrode 126 resides in the pre-chamber 120 and is operable therein at a first frequency and is adapted to produce plasma in the processing chamber 105. The RF electrode 126 may comprise a conductive metal plate for voltage upholding and ceramic isolation pieces, as is conventional. RF electrode 126 is electrically coupled to, and driven by, an RF source 127. RF source 127 is driven responsive to signals from an RF pulse generator 128, which will be explained further below.

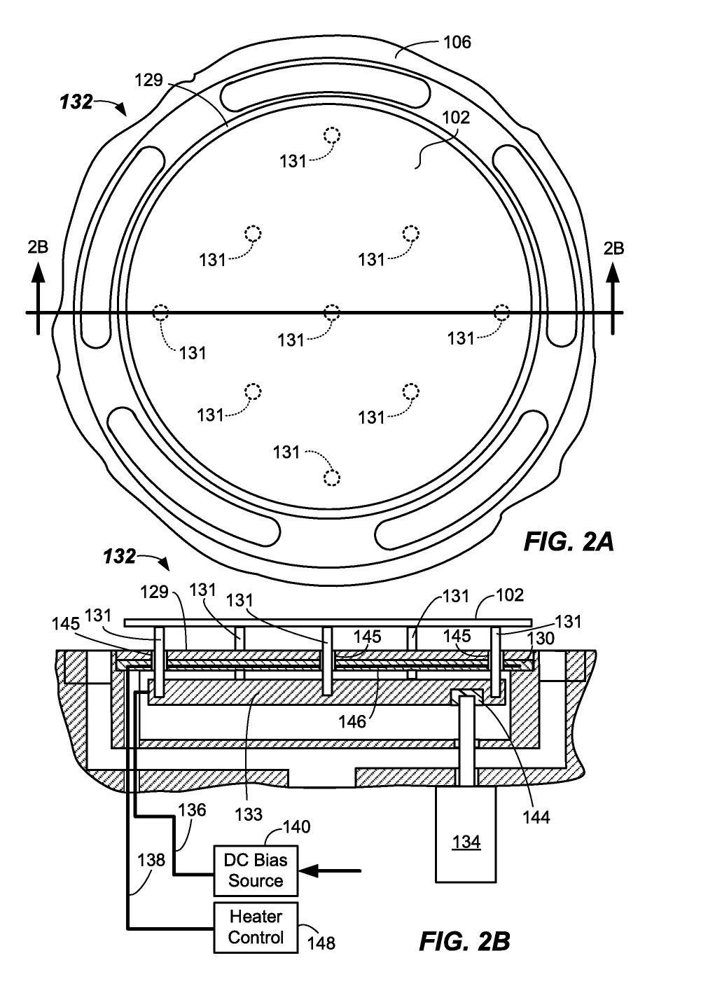

The substrate etching apparatus 100 also includes a pedestal 129 located in the process chamber 105 and adapted to support the substrate 102 at times. The pedestal 129 may be stationarily mounted to the body 106. Pedestal 129 may include a heater 130 (FIG. 2B) to heat the substrate 102 prior to starting the etching process. Heater 130 may be a suitable heater, such as a resistive heater and may be operable to heat the pedestal 129 to a temperature of between about 30 degrees C. to about 250 degrees C., or more, for example. Other temperatures may be used. During processing, a plurality of conductive pins 131 (several labeled) are configured and adapted to lift, contact, and support the substrate 102 at a defined height within the process chamber 105 during the etching process, as shown in FIG. 1. The plurality of conductive pins 131 may be part of a conductive pin assembly 132 comprising a base 133 with the conductive pins 131 extending therefrom. The number of conductive pins 131 may be more than three. In some embodiments, the number of conductive pins 131 may be five or more, or even 9 or more, for example. More or less numbers of conductive pins 131 may be used. Pins 131 made of a conductive metal, such as W/Ti alloy, and may have a length of between about 30 mm and about 60 mm, and a diameter of between about 5 mm and about 15 mm. In some embodiments, the substrate 102 may be placed by the conductive pins 131 within between about 10 mm and about 50 mm from the showerhead 124 during plasma processing. Other dimensions, spacings and/or conductive materials may be used. The conductive pin electrical connection during processing may avoid charge-induced ramp-up/ramp-down during pulsing.

FIGS. 2A and 2B illustrate a conductive pin assembly 132 and the electrical connections thereto. An actuator 134 coupled to the base 133 may be actuated to lift or lower the conductive pins 131 in the vertical direction, and thus lift or lower the substrate 102 at various times during the processing. First and second electrical cables 136, 138 electrically connect to the assembly 132. Base 133 may be an electrically conductive metal, such as steel, copper or aluminum. In the depicted embodiment, a DC bias source 140 is electrically coupled to the plurality of conductive pins 131 through the electrical cable 136 being coupled to an electrically conductive base 133. A DC pulse generator 142 (FIG. 1) provides a pulsed drive signal to the DC bias source 140 and a pulse DC bias is provided to the conductive pins 131. In order to insulate the actuator 134, the connection to the base 133 may comprise an insulating connector 144.

The pedestal 129 may comprise a ceramic material such as glass ceramic or metal carbide having a plurality of holes 145 formed therein. The conductive pins 131 are received in and pass through the holes 145 and are reciprocal therein responsive to actuation of the actuator 134. In some embodiments, the conductive pins 131 may extend through the holes 145 by between about 10 mm and about 30 mm, for example. Other values may be used. The heater 130, such as a resistive heater may be received underneath the pedestal 129 or otherwise thermally coupled thereto, and is configured and operable to heat the pedestal 129 via power supplied from the heater control 148 by the second cable 138.

In operation, pins 131 may be first raised to receive a substrate 102 that is inserted through the opening 108 on the end effector 109 of a robot housed in the transfer chamber 111. The slit valve apparatus 110 may be closed and the pins 131 may be lowered by actuator 134 to bring the substrate 102 into intimate thermal contact with the heated pedestal 129. A pump 149, such as a vacuum pump may pump down the process chamber 105 to a suitable vacuum level for etching. In some embodiments, base vacuum level may be maintained at a pressure of below about 1×10⁻² mTorr, whereas processing pressure may be maintained in the range of about sub 10 mTorr to about sub Torr level. Other vacuum pressures may be used.

After the substrate 102 is sufficiently heated and a suitable chamber pressure is provided, the actuator 134 may cause the conductor pins 131 to raise and contact the substrate 102 and raise the substrate 102 to a predetermined location in the process chamber 105. The first process gas 113 may be flowed into the inlet 122 from the process gas source 114 and an RF pulse is applied to the RF electrode 126. Similarly, a DC bias pulse is applied to the conducting pins 131 from the DC bias source 140. UV light may be supplied to the process chamber 105 using UV light source 101.

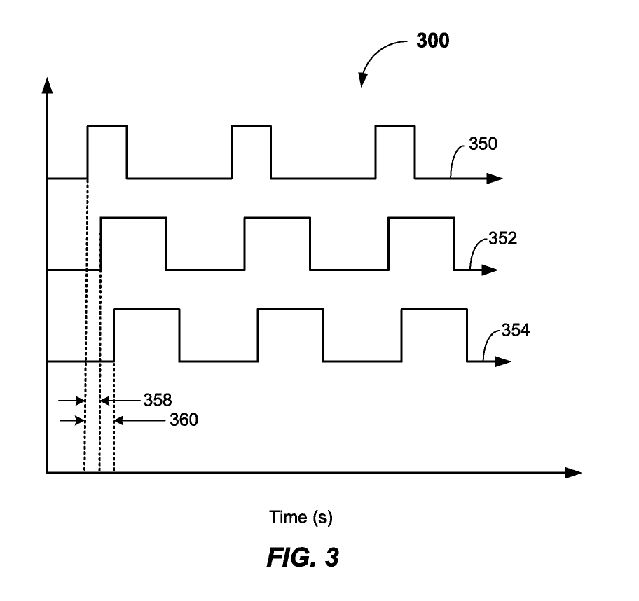

In the depicted embodiment shown in FIG. 3, the various pulse traces 300 of the master clock pulse 350, RF pulse 352 applied to the RF electrode 126, and the DC bias pulse 354 applied to the conductive pins 131 are each shown against the same time axis. In some embodiments, the RF pulse generator 128 and the DC pulse generator 142 may be synchronized by a master clock 155 and each are voltage signals. Further, both the RF pulse generator 128 and the DC pulse generator 142 may have a time delay instituted relative to the master clock signal 350 produced by the master clock 155. An RF delay 358 and a DC bias delay 360 (e.g., delay 1 and delay 2) may be separately adjustable, and may be determined and set by process control 156 based upon experimental etching runs. The frequency of each of the RF pulse 352 and the DC bias pulse 354 may be adjusted by adjusting the frequency of the master clock 155, for example. A frequency multiplier may be used. Thus in some embodiments, the frequency of the RF pulse 352 may be different than (e.g., any multiple of) the DC bias pulse 354. For example, the RF pulse 352 may be operated at twice the DC bias pulse 354 in some embodiments. Other multiples may be used.

The DC bias pulse 354 may comprise square wave pulses having a frequency of between about 1 MHz to about 60 MHz, for example. The frequency of the DC bias pulses 354 may be varied in some embodiments. The DC bias pulse 354 may have a pulsing duty cycle from about 10% to about 90%, for example. Duty cycle is defined herein as the fraction of on time (at peak power) over one full period. The DC bias pulse 354 may nave a peak power of between about 10 W to about 2,000 W, for example. In some embodiments, the DC bias pulse 354 may be pulsed from a positive voltage (in the On condition) to a negative voltage (in the Off condition). In other embodiments, the DC bias pulse 354 may be a positive voltage with a superimposed pulsed voltage, but the applied voltage to the pins 131 is always positive, with the peak voltage in the on condition and a lesser on the off condition. The peak ampitude of the DC bias pulse 354 may be modulated per pulse, in any desired pattern, or randomly.

The applied RF pulse 352 may have a frequency of between about 2 MHz and about 120 MHz, for example. The RF pulse 352 may have an applied peak RF power between about 100 W to about 3,000 W. A frequency of the RF pulses 352 may be varied in some embodiments. In other embodiments, a frequency of the RF pulses 352 and the frequency of the DC bias pulses 354 are varied. The bias delay 360 may be adjusted to provide a period of time for each pulse after the RF returns to the Off condition to allow for a residue reaction with any process residue remaining after the RIE (Reactive Ion Etching) phase. The RF delay 358 and bias delay 360 may be adjusted between 1% and about 80% of the master clock. Other delays may be used.

To facilitate control of the etching process, controller 162 may be coupled to the various apparatus components. The controller 162 may be provided in the form of a general-purpose computer processor or micro-processor that may be used for controlling various functions. The controller 162 may include a processor and memory such as random access memory (RAM) read only memory (ROM), a floppy disk, a hard disk, or any other form of digital storage, either local or remote. Various electrical circuits may embody the process control 156, master clock 155, R/F pulse generator 128, DC pulse generator as well as RF source 127 and DC Bias source 140. These circuits may include cache, power supplies, clock circuits, amplifiers, modulators, comparators, filters, signal generators, input/output circuitry and subsystems, and/or the like. Controller 162 may also control operation of UV source 101. For example, controller 162 may direct UV source 101 to provide UV irradiation to the process chamber 105 at any time during an etch process (e.g., beginning, middle and/or end). In some embodiments, UV light having a wavelength of about 150-400 nanometers, or about 3 eV-8 eV of energy, and/or a flux rate of about 1×10¹⁵-1×10¹⁸ photons/(cm²-min) may be employed. Other wavelengths, energies and/or flux rates may be employed.

The inventive methods disclosed herein may generally be stored in the memory, or computer-readable medium as a software routine that, when executed by the processor, causes the process chamber 105 to perform the etching process on the substrate 102 according to embodiments of the present invention.

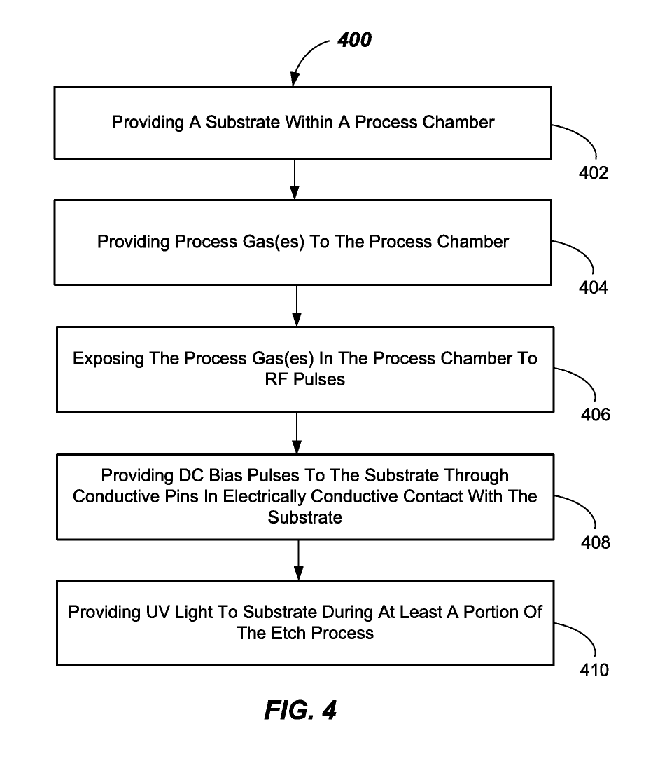

FIG. 4 illustrates a plasma etching method 400 adapted to etch a substrate (e.g., substrate 102). The plasma etching method 400 includes, in 402, providing the substrate within a process chamber (e.g., process chamber 105), and providing one or more a process gases (e.g., process gas 113) to the process chamber in 404. The method 400 further includes, in 406, exposing the process gas(es) in the process chamber to RF pulses (e.g., RF pulses 352), and, in 408, providing DC bias pulses (e.g., DC bias pulse 354) to the substrate through conductive pins (e.g., conductive pins 131) in electrically conductive contact with the substrate. The method 400 further includes, in 410, providing UV light (e.g., from UV source 101) to the substrate and/or process chamber during at least a portion of the etching method 400. In some embodiments, the DC bias, process gas(es) and/or UV light may be provided cyclically and/or in other orders. The UV light provides a supplement energy source for driving the etch process and facilitating etch residue removal at lower process temperatures. The use of a lower etch temperature also allows for more control during etch by balancing etch rate with uniformity and profile considerations, while UV assisted residue removal allows for greater control over isotropic reactions and a larger process window. In some embodiments, UV light having a wavelength of about 150-400 nanometers, or about 3 eV-8 eV of energy, and/or a flux rate of about 1×10¹⁵-1×10¹⁸ photons/(cm²-min) may be employed. Other wavelengths, energies and/or flux rates may be employed.

From the applied RF pulses 352 and DC bias pulses 354, plasma is formed from the process gas 113. Generally, to form the plasma, the process gas 113 may be ignited into plasma. by coupling RF power from the RF source 127 at a suitable frequency to the process gas 113 within a process chamber 105 under suitable conditions to establish the plasma. In some embodiments, the plasma power source may be provided via an RF electrode 126 that is disposed within the pre-chamber 120 or process chamber 105. Optionally, the RF power source may be provided by or more RF induction coils that are disposed within or surrounding the body 106 and act as an RF electrode. In other embodiment, the RF source may be a remote source, such as is taught in U.S. Pat. No. 7,658,802 to Fu et al. Other suitable sources may be used to produce the RF pulses.

The apparatus and method described herein are particularly effective for removing non-volatile residues that form during the etching process itself. in accordance with an aspect of the invention, the DC power damping location is controlled by the pulsing frequency. At a low frequency range (e.g. <10 MHz, depending on the relation between ion transit time and pulsing frequency) DC bias power is coupled to the plasma sheath, which increases the ion etchant energy. At a higher frequency range (e.g., >10 MHz), power coupling contributes to bulk plasma for improved plasma density and potential control. The etchant energy may be further controlled by duty cycle and DC bias power input. Accordingly, etch rate and trench profile shape may be improved. Bias amplitude modulation may be provided to separate the desired surface reaction (etching) versus undesired processes. During the “DC bias-On” periods of DC bias pulses 354, reactive etchants gain energy and perform controlled etching within the duty cycle. For “DC bias-Off” periods, plasma is transferred to new equilibrium for etch residue purge and reactive etchant cycling. DC bias may be modulated between about 10% and about 100% of the peak power.

The DC bias pulses 354 can be applied for either dielectric and/or conductive materials/substrate etching processes with requirements of broad process window and precise specification control, including etch depths, CD/CD uniformity, and trench profile. The present method and apparatus may be useful for 20 nm technology node and beyond.

In particular, UV irradiation and/or DC bias pulsing may be significantly beneficial to etch processes, during which non-volatile byproducts are developed. For example, such etching processes include copper etch with CuX, where X═Cl, Br, and the like, and/or CuO residues, TiN etch with TiF, TiOF, TiOx residues, SiN etch with SiON residue, or oxidized layers, Ru etch and related residue, and the like. The non-volatile byproducts (residues) can be more selectively and efficiently removed by embodiments of the present method and using the apparatus 100 described herein.

Additional process parameters may be utilized to promote plasma ignition and plasma stability. For example, in some embodiments, the process chamber 105 may be heated by heater elements (not shown) in thermal contact with the body 106 and maintained at a temperature of between about 60 to about 100 degrees Celsius during plasma ignition.

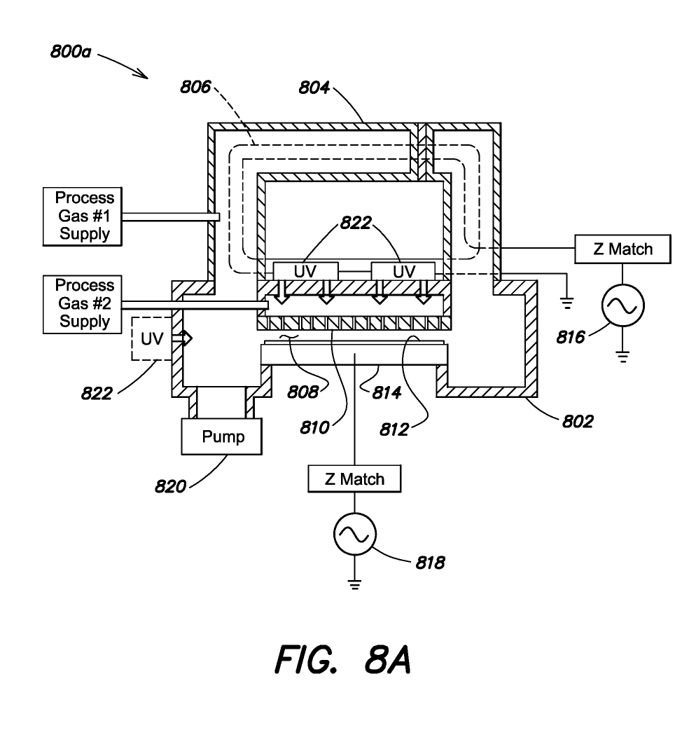

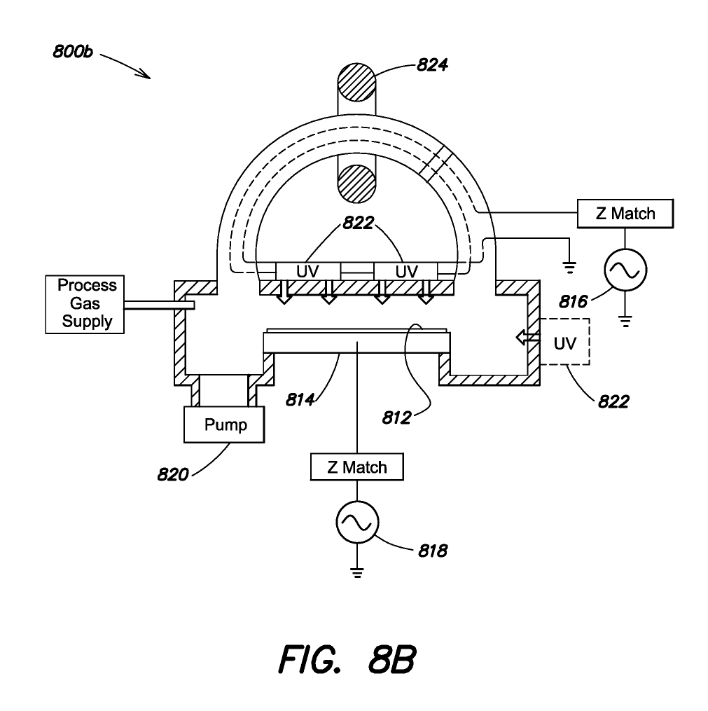

FIGS. 8A and 8B are cross sectional views of example torroidal plasma chambers according to some embodiments. FIG. 8A illustrates a first torroidal plasma chamber 800a that includes a plasma chamber 802 having a torroidal conduit 804 and an RF coil antenna 806 for exciting plasma in the conduit 804 and main chamber region 808. Process gases may be supplied to both the conduit 804 and main chamber region 808, and dispersed within the main chamber region 808 with a shower head 810. A substrate 812 may be supported within the chamber region 808 on a heated pedestal 814, for example. The RF coil antenna 806 may be driven by an RF power supply 816 and the pedestal 814 may be biased with an RF power supply 818. A pump system 820 may be employed to evacuate the chamber 802 to a desired pressure and/or to remove volatile etch byproducts.

In some embodiments, one or more UV light sources 822 may be employed to provide UV irradiation to the chamber region 808 and/or substrate 812 during etching. In the embodiment shown, the UV source 822 is located on a lid of the chamber 802 (e.g., above a port or window (now shown) that allows the UV light to enter the chamber region 808). Alternatively or additionally, the UV light source may be located on one or more sidewalls of the chamber 802 as indicated by the UV source 822 in phantom. Any other location may be employed. FIG. 8B illustrates a second torroidal plasma chamber 800b with a slightly different configuration (e.g., including a magnetic permeable core 824). Torroidal plasma chambers are described in previously incorporated U.S. Pat. No. 6,453,842.

The UV light provides a supplement energy source for driving etch processes and facilitating etch residue removal at lower process temperatures. For example, at least one of a process gas and a substrate may be exposed to UV light during at least a portion of a plasma etching process. The use of a lower etch temperature also allows for more control during etch by balancing etch rate with uniformity and profile considerations, while UV assisted residue removal allows for greater control over isotropic reactions and a larger process window.

Accordingly, while the present invention has been disclosed in connection with example embodiments thereof, it should be understood that other embodiments may fall within the scope of the invention, as defined by the following claims.

The invention claimed is:

1. A copper plasma etching method, comprising:
providing a substrate within a process chamber;
providing a process gas to the process chamber;
exposing the process gas in the process chamber to RF pulses;
plasma etching the substrate within the process chamber; and
exposing at least one of the process gas and substrate to UV light during at least a portion of the plasma etching.

2. The method of claim 1, further comprising providing DC bias pulses to the substrate through conductive pins in electrically conductive contact with the substrate.

3. The method of claim 2, comprising varying a frequency of the DC bias pulses.

4. The method of claim 2, comprising varying a frequency of the RF pulses and the frequency of the DC bias pulses.

5. The method of claim 2, comprising varying a duty cycle the DC bias pulses.

6. The method of claim 2, comprising modulating amplitude of the DC bias pulses.

7. The method of claim 1, comprising removing copper residue from the substrate.

8. The method of claim 2, wherein the DC bias pulses have a bias power of between about 10 W and about 2,000 W.

9. A copper plasma etching method, comprising:
providing a substrate within a process chamber;
providing a process gas to the process chamber;
exposing the process gas in the process chamber to RF energy to generate a plasma within the process chamber;
plasma etching the substrate within the process chamber; and
exposing at least one of the process gas and substrate to UV light during at least a portion of the plasma etching.

10. The method of claim 9, further comprising providing DC bias pulses to the substrate through conductive pins in electrically conductive contact with the substrate.

11. The method of claim 10, comprising varying a frequency of the DC bias pulses.

12. The method of claim 10, comprising exposing the process gas in the process chamber to RF pulses having varying a frequency.

13. The method of claim 10, comprising varying a duty cycle the DC bias pulses.

14. The method of claim 10, comprising modulating amplitude of the DC bias pulses.

15. The method of claim 9, comprising removing copper residue from the substrate.

16. The method of claim 10, wherein the DC bias pulses have a bias power of between about 10 W and about 2,000 W.

17. A method comprising:
generating a plasma from a process gas for etching copper on a substrate;
providing DC bias pulses to the substrate;
exposing at least one of the plasma and the substrate to UV light while the DC bias pulses are provided to the substrate.

18. The method of claim 17, comprising varying a frequency of the DC bias pulses.

19. The method of claim 17, wherein generating a plasma includes exposing the process gas to RF pulses having varying a frequency.

20. The method of claim 17, comprising modulating amplitude of the DC bias pulses.
